(19) United States
(12) Patent Application Publication
(10) Pub. No.: US 2025/0260366 A1
(43) Pub. Date: Aug. 14, 2025

(54) RF PULSE AMPLIFIER COMPRISING A DC/DC CONVERTER AND METHOD OF AMPLIFYING AN RF PULSE

(71) Applicant: PRODRIVE TECHNOLOGIES INNOVATION SERVICES B.V., Son en Breugel (NL)

(72) Inventor: Bart Gerardus Maria VAN ARK, Son en Breugel (NL)

(21) Appl. No.: 18/705,822

(22) PCT Filed: Nov. 3, 2022
(86) PCT No.: PCT/EP2022/080718

§ 371 Date: Apr. 29, 2024

(30) Foreign Application Priority Data
Nov. 8, 2021 (NL) 2029664

(51) Int. Cl. H03F 1/02; G01R 33/36; H03F 3/24

(52) U.S. Cl. CPC H03F 1/0227; G01R 33/3614; H03F 3/245; H03F 2200/451

(57) ABSTRACT

An RF pulse amplifying device includes an amplifier configured to amplify a pulsed RF signal, a DC link configured to supply a DC bus voltage, and an energy storage device connected to the DC link. The amplifier has an input for receiving a supply voltage. The input of the amplifier is connected to the DC link through a switched DC/DC converter, which is configured to step down the DC bus voltage, supplied at the converter input, to the supply voltage, applied to the converter output. A control unit is configured to operate the switched DC/DC converter during amplification of the RF pulse to control the supply voltage at a predetermined value.

### TECHNICAL FIELD

The present disclosure is related to radio frequency (RF) pulse amplifying devices, in particular comprising an RF amplifier and an energy storage device for providing the peak power during amplification of the pulse.

### BACKGROUND

Pulsed RF applications, such as magnetic resonance imaging (MRI), require a high peak power for a short time in the order of several milliseconds to generate one pulse. The peak to average power ratio in these applications is typically in the range of 5 to 40. This requires either a large energy (capacitor) buffer, or a power supply capable of delivering the peak power. The latter solution is however not preferred due to the large impact on the grid capacity and the added cost and footprint of a power supply dimensioned based on the peak power instead of the average power.

One disadvantage of utilizing an energy buffer for delivering the peak power is that it results in voltage droop at the energy buffer when the rate of depletion of the buffer exceeds the rate of renewal from the power supply. This typically occurs during generation of the pulse. The RF output power is directly related to the DC voltage supplied to the amplifier by the energy buffer through the relation: P_{RF}=V_{DD}²/β, where β represents a constant depending on the load impedance and used transistor power capability. If the energy buffer is simply attached to the amplifier, the pulse power is reduced, resulting in an RF power droop. This phenomenon particularly occurs when the amplifier is operated in compression.

RF power droop problems have become more pronounced by the introduction of LDMOS (laterally-diffused metal-oxide semiconductor) transistor technology (supply voltage V_{DD}=50V) in RF amplifiers compared to previously used VDMOS (vertical double-diffused metal-oxide semiconductor) transistor technology (supply voltage V_{DD}=150V). The constant β for LDMOS is 9 times lower compared to VDMOS resulting in much higher supply currents for the same RF power. A supply voltage droop of 1V for a VDMOS RF amplifier typically results in 1.3% RF power droop, where 1V voltage droop for a LDMOS RF amplifier typically results in 4% RF power droop. In other words, for having equal RF power droop for LDMOS as compared to VDMOS, the supply voltage should be lower than 330 mV. RF power droop problems are also pronounced for GaN transistor devices, which also feature a 50 V supply voltage.

U.S. Pat. No. 6,072,315, 6 Jun. 2000 describes a RF magnetic field pulse generator comprising an energy storage device and a switched voltage regulator which regulates the supply voltage of the RF amplifier. The energy storage device is connected to the amplifier via the switched voltage regulator, which comprises a local storage capacitor. The supply voltage is defined by the voltage across the local storage capacitor. The switched voltage regulator controls when the local storage capacitor is charged from the energy storage device. The recharge logic is such that the local storage capacitor is charged in synchronism with a pulse train, and such that the local storage capacitor is not charged during a pulse, but only in between consecutive pulses. U.S. Pat. No. 6,072,315 appreciates that the supply voltage may change during the course of one pulse. However, the voltage regulator ensures that the supply voltage is restored to the correct level in time for the next pulse.

While the approach of U.S. Pat. No. 6,072,315 may be acceptable for very short pulses of the order of a few microseconds, it is not acceptable for longer pulses of the order of a few milliseconds, as is customary in e.g. MRI applications.

US 2017/0102441, 13 Apr. 2017 describes a pulsating load, such as an RF amplifier power supply, connected to the three-phase AC mains through a passive rectifier. An energy storage device, such as an ultracapacitor, is connected through a DC/DC converter to the DC link created by the passive rectifier. The energy storage device connects through the DC/DC converter downstream of the rectifier and upstream from the RF amplifier power supply. Power is shared between AC mains and the energy storage device during a pulsing period and power drawn during a non-pulsing period is utilized by the energy storage device to charge back. The release of energy from the energy storage device during peak load power duration, results in reducing the power and hence the current drawn from the AC mains.

One disadvantage of the above system, is that to prevent significant RF power droop, a large capacitor bank is required as the energy storage device, resulting in high cost and volume. Nevertheless, even in such cases, RF power droop cannot be completely avoided.

### SUMMARY

There is hence a need in the art to provide RF pulse amplifiers that can overcome the disadvantages of the prior art. Specifically, there is a need for RF pulse amplifiers that can achieve better performance at reduced cost and volume.

According to a first aspect of the present disclosure, there is therefore provided a device for amplifying a radio frequency (RF) pulse. In aspects of the present disclosure, a RF pulse amplifying device comprises an amplifier configured to amplify a pulsed RF signal, a DC link configured to supply a DC bus voltage, and an energy storage device connected to the DC link. The amplifier comprises an input for receiving a supply voltage. The input of the amplifier is connected to the DC link (and hence to the energy storage device) through a switched (or switched-mode) DC/DC converter, which is configured to step down the DC bus voltage (supplied at the converter input) to the supply voltage (applied to the converter output). A control unit is configured to operate the switched DC/DC converter during operation of the RF amplifier (i.e. when amplifying the RF pulse) to control the supply voltage at a predetermined value. Advantageously, the control unit is configured to control the switched DC/DC converter to switch continuously, i.e., both during generation or amplification of a pulse and in between consecutive pulses of the pulsed RF signal. Hence, advantageously the switched DC/DC converter is configured to switch continuously during operation of the device, independently of whether a pulse is applied.

The device described in the present disclosure hence allows to efficiently control the supply voltage at the input of the amplifier to a predetermined value, irrespective of variations in the DC bus voltage of the DC link. This DC bus voltage may be allowed to vary in a wide range, relaxing the specifications required for the energy storage device and any upstream mains-to-DC converter in terms of voltage droop. At the same time, the supply voltage can be tightly controlled so that any occurring voltage droop at the DC link does not propagate to the output of the amplifier, effectively preventing RF output power droop. Hence, devices as described herein provide high performance at minimal cost and volume.

Advantageously, the switched DC/DC converter is configured to be operated (e.g. through the control unit) at a switching frequency, which is substantially higher than the repetition frequency of the RF pulse. A ratio of the switching frequency to the repetition frequency of the RF pulse is at least 10, preferably at least 20, preferably between 50 and 10000. This allows to effectively control the supply voltage to a stable value. Advantageously, the switched DC/DC converter is configured to be operated continuously. The switched DC/DC converter can be a non-isolating converter, e.g. a half bridge converter, which provides a very economical pulse generator with minimal volume while ensuring high performance. Alternatively, it can be an isolating converter.

Hence, in devices as described herein, the amplifier is connected to the energy storage device, which can comprise one or more storage capacitors, such as a capacitor bank, through the switched DC/DC converter. The energy storage device can be connected to the mains supply, e.g. an AC supply, through a mains-to-DC converter. The mains-to-DC converter advantageously comprises an output connected to the DC link. The mains-to-DC converter is advantageously configured to supply energy to the energy storage device, and the mains-to-DC converter is advantageously rated based on an average output power of the amplifier.

In some examples, a plurality of series arrangements of the switched DC/DC converter and the amplifier are provided. Each amplifier receives a supply voltage from the respective switched DC/DC converter. The series arrangements of switched DC/DC converter and amplifier can be connected in parallel at the output of the amplifier, e.g. through a power combiner and/or at the input of the switched DC/DC converter, e.g. at the DC link. This way, a RF pulse amplifying device with higher output power can be provided.

According to a second aspect of the present disclosure, there is provided an apparatus for generating a RF electromagnetic field, such as a magnetic resonance imaging apparatus, a plasma generating apparatus, a particle accelerator, or a laser apparatus, comprising the device as described herein.

According to a third aspect of the present disclosure, there is provided a method of amplifying a RF pulse. A method according to the present disclosure comprises storing energy in an energy storage device at a DC bus voltage and stepping down the DC bus voltage to a supply voltage utilizing a switched DC/DC converter. The supply voltage is applied to an amplifier, which amplifies the RF pulse. The switched DC/DC converter is operated while amplifying the RF pulse. Advantageously, the amplifier outputs RF pulses at a pulse repetition frequency and the switched DC/DC converter is operated at a switching frequency, wherein a ratio of the switching frequency to the pulse repetition frequency is at least 10, preferably at least 20, preferably between 50 and 10000.

Advantageously, a ratio of the DC bus voltage to the supply voltage is at least 1.5, preferably at least 2. A larger ratio of DC bus voltage to supply voltage allows for a larger voltage variation of the DC bus voltage during pulse generation (e.g. due to voltage droop). The DC bus voltage can be between 20 V and 500 V, particularly between 70 V and 300 V. The supply voltage is advantageously between 5 V and 200 V, preferably between 12 V and 150 V, or between 28 V and 100 V.

### BRIEF DESCRIPTION OF THE DRAWINGS

Aspects of the present disclosure will now be described in more detail with reference to the appended drawings, wherein same reference numerals illustrate same features and wherein:

FIG. 1 represents a schematic diagram of a device for amplifying RF pulses according to aspects of the present disclosure;

FIG. 2 represents a diagram of a non-isolated DC/DC converter that can be utilized in the device for amplifying RF pulses according to aspects of the present disclosure;

FIG. 3 represents a schematic diagram of an isolated DC/DC converter that can be utilized in the device for amplifying RF pulses according to aspects of the present disclosure;

FIG. 4 represents a schematic diagram of a device for amplifying RF pulses according to aspects of the present disclosure comprising a plurality of amplifiers and a RF power combiner.

### DETAILED DESCRIPTION

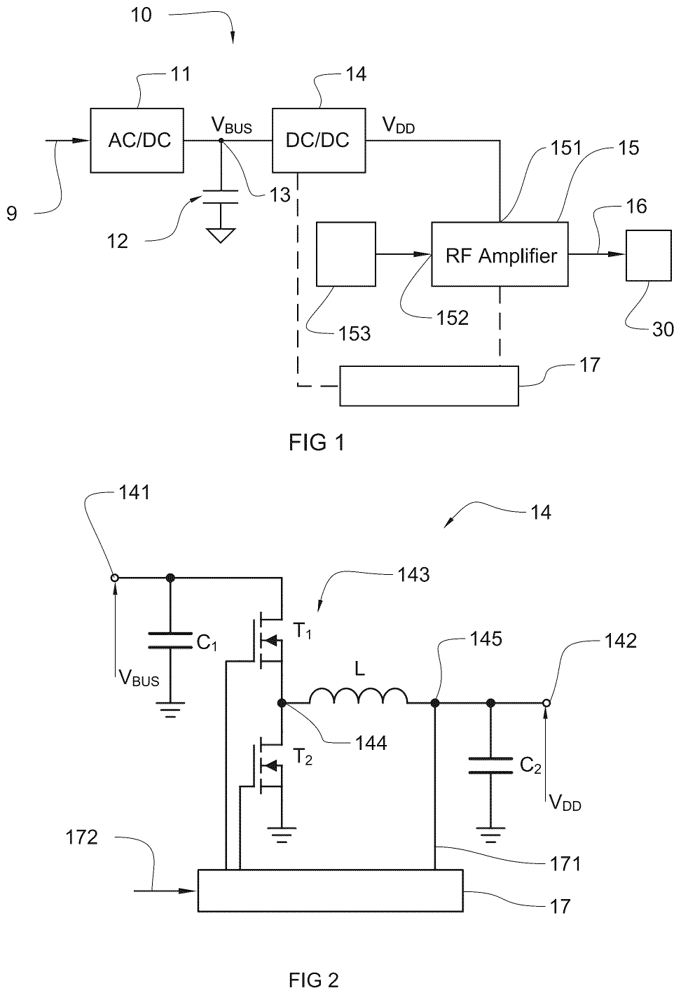

Referring to FIG. 1, a device 10 for amplifying RF pulses according to the present disclosure is configured to provide an amplified RF pulsed signal, which can comprise one or more pulses, at an output 16. The RF pulsed signal is generated by a signal generator 153 and supplied to RF amplifier 15 at a signal input 152. RF amplifier 15, which can be any suitable power amplifier as known in the art capable of amplifying a pulsed RF signal, preferably a class B or class E amplifier, is configured to amplify the pulsed RF signal received at signal input 152 and provide the amplified signal at output 16. The RF pulses, which advantageously are AC pulses, can have a pulse duration of the order of a few milliseconds, such as between 1 ms and 100 ms, preferably between 1 ms and 50 ms, even though shorter pulses, e.g. of the order between 50 μs and 1 ms are possible. The pulse duty-cycle can range between 0.5% and 25%, and is typically between 1% and 10%. The power delivered by a pulse can range between 1 kW and 100 kW, possibly between 2 kW and 60 kW, such as between 5 kW and 50 kW, for example about 20 kW, which is typical for MRI applications.

RF amplifier 15 comprises an input 151 for receiving a supply voltage V_{DD}. For RF amplifiers based on LDMOS or GaN transistors, the supply voltage V_{DD} may range between 12 V and 100 V, and is typically V_{DD}=50 V. The power delivered by the RF amplifier 15 at the output 16 is typically directly related to the supply voltage.

The input 151 of RF amplifier 15 is connected to the DC link 13 through a DC/DC buck converter 14. The DC link is at a bus voltage V_{BUS} which is higher than the supply voltage V_{DD} and the DC/DC converter is configured to step down the bus voltage V_{BUS} to the supply voltage V_{DD}.

An energy storage device 12, which acts as an energy buffer, is connected to DC link 13. Energy storage device 12 can comprise a capacitor bank, or one or more ultracapacitors, or any other energy buffering system as known in the art. Energy storage device buffers electrical energy typically at the bus voltage V_{BUS} of DC link 13. Energy storage device is charged via a mains supply 9, typically providing AC power. An AC/DC converter 11 is connected between the mains supply 9 and the energy storage device 12. Particularly, the AC/DC converter 11 comprises a DC output connected to the DC link 13 and the energy storage device 12 is connected to the DC link 13. The AC/DC converter 11 can be an active or a passive rectifier as is known in the art.

Advantageously, the AC/DC converter 11 is rated based on the average power requested by RF amplifier 15. The output power provided by AC/DC converter 11 can be limited to the average power requested by, or rated for RF amplifier 15. While the peak power required by RF amplifier 15 during generation of a pulse is typically 5 to 40 times higher, the energy storage device 12 and DC/DC converter 14 are sized to be capable of delivering the demanded peak power.

Voltage droop of the bus voltage V_{BUS} inevitably occurs during pulse amplification due to a discharging energy storage device. To prevent the voltage droop of V_{BUS} diffusing to the RF amplifier supply voltage V_{DD}, the bus voltage is chosen to be higher than the RF amplifier supply voltage V_{DD}, and a switched (or switched-mode) DC/DC buck converter 14 is configured to step-down the bus voltage V_{BUS} to the supply voltage V_{DD}. DC/DC converter 14 is hence configured to operate, i.e., switch, during pulse amplification, and advantageously to operate, i.e., switch, continuously, to provide a controlled and substantially stable supply voltage V_{DD}. Hence, while the bus voltage V_{BUS} may vary when power is drawn from the RF amplifier, in particular during amplification of a pulse, the DC/DC converter is controlled to maintain the supply voltage V_{DD} substantially constant irrespective of a change of V_{BUS}. As a result, the device according to the present disclosure avoids RF power droop resulting from voltage droop at the bus voltage of the energy buffer.

The specifications of the energy storage device 12 with respect to voltage droop can hence be relaxed, since the voltage variation will be absorbed by controlling operation of the switched DC/DC converter 14. Hence, energy storage device 12 can be designed as a much smaller energy buffer compared to prior art solutions, allowing to reduce volume and cost of the device according to the present disclosure compared to existing RF pulse amplifying devices. In addition, the specifications of the AC/DC converter 11 can be relaxed as well, since the converter 11 needs to be designed for the average output power of the device 10. The AC/DC converter 11 can operate continuously, irrespective of the amplification of a pulse by RF amplifier 15, to charge the energy storage device 12 and compensate any idle losses (e.g. of DC/DC converter 14) for maintaining a predetermined voltage V_{BUS} on the DC link 13. A suitable control logic can be provided which operates AC/DC converter 11 on the basis of the sensed voltage level of the bus voltage V_{BUS}.

The ratio V_{BUS}/V_{DD} (rated values) is advantageously at least 1.3, advantageously between 1.5 and 20, possibly between 1.7 and 10, such as 2, 2.5 or 3. The larger the ratio V_{BUS}/V_{DD}, the larger the allowable voltage variation on V_{BUS}. A voltage variation of at least 20% on V_{BUS} during generation of a pulse can be allowed. In some examples a voltage variation of at least 30%, or at least 50% on V_{BUS} can be allowed.

Referring to FIG. 2, a specific example of a switched DC/DC converter 14 is provided as a non-isolated half bridge converter. Half bridge 143 comprises controllable high-side switch T₁, which can be a MOSFET (metal oxide semiconductor field effect transistor) or IGBT (insulated gate bipolar transistor) switch device having unidirectional or bidirectional current blocking capability and a low-side switch T₂, which can be a controllable switch (e.g. MOSFET or IGBT as with T₁) or a passive device with current blocking capability, such as a diode. The upper node of half bridge 143 is connected to the input terminal 141 of DC/DC converter 14. Input terminal 141 can be connected to the positive rail of the DC link 13. The lower node of half bridge 143 can be connected to the negative rail of the DC link 13, or as shown in FIG. 2, to a common ground. The middle node 144 of half bridge 143, between the switches T₁ and T₂, is connected to the output terminal 142 of DC/DC converter 14 through an inductor L.

A local input capacitor C₁ can be connected with its positive terminal to the input terminal 141. The negative terminal of C₁ can be connected to the common ground, or, as the case may be, to the negative rail of DC link 13. The bus voltage V_{BUS} hence is provided across local input capacitor C₁. Local input capacitor C₁ is utilized to provide local decoupling. It is not, in principle, configured for buffering energy. A local output capacitor C₂ can be connected with its positive terminal to the output terminal 142. The negative terminal of C₂ can be connected to the common ground, or as the case may be, to a negative input terminal of RF amplifier 15. The supply voltage V_{DD} is provided across local output capacitor C₂. As with C₁, local output capacitor C₂ is merely provided for local decoupling. It is not, in principle, configured for buffering energy.

Control unit 17 controls operation of switch T₁ and possibly T₂ (in case T₂ is controllable) of half bridge 143, e.g. through pulse width modulation (PWM). A voltage sensor 145 measures the supply voltage V_{DD}, e.g. at output terminal 142, and provides a feedback signal 171 to the control unit 17. This way, control unit 17 can control the supply voltage V_{DD} to be substantially at a predetermined value irrespective of changes in the bus voltage V_{BUS} through appropriately adapting the duty cycle of T₁ (and possibly T₂). Control unit 17 can comprise an input 172 for receiving a set value of the supply voltage V_{DD}. Such a half bridge converter provides high performance at minimal cost and volume.

Referring again to FIG. 1, control unit 17 can additionally control operation of the RF amplifier 15, in particular controlling the generation of the RF pulsed signal. Additionally, or in the alternative, control unit 17 can control operation of AC/DC converter 11.

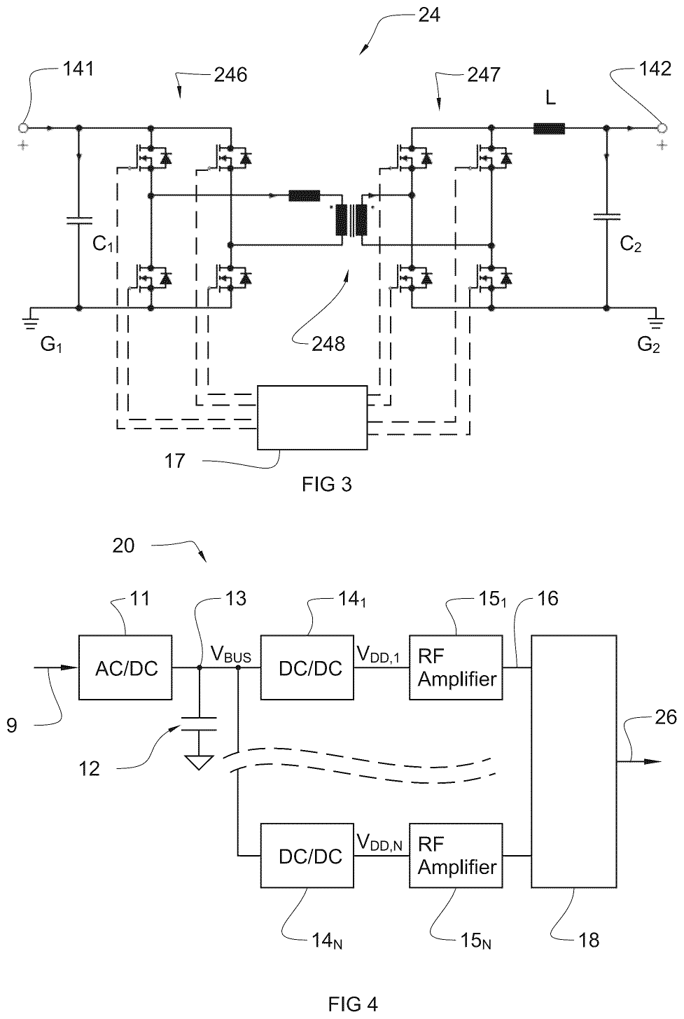

Other converter topologies can be utilized for DC/DC converter 14. By way of example, referring to FIG. 3, it may be convenient to provide an isolating DC/DC converter 24, such as including a transformer 248 providing galvanic isolation between the input terminal 141 and the output terminal 142 of DC/DC converter 24. DC/DC converter 24 comprises a first full bridge converter circuit 246 connected to the input terminal 141 and a first ground node G1, and a second full bridge converter circuit 247 connected to the output terminal 142 and second ground node G2. The first and second full bridge converter circuits 246, 247 are coupled through a transformer 248 providing galvanic isolation, e.g. having 1:1 winding ratio, even though any other suitable winding ratio can be used. The switches in the bridge legs of the first full bridge converter circuit 246 can be active semiconductor switching devices, in which case they are operated through control unit 17. The switches in the bridge legs of the second full bridge converter circuit 247 can be active or passive semiconductor switching devices. It will be convenient to note that ground nodes G1 and G2 should be galvanically isolated. Plenty of isolated DC/DC converter topologies can be utilized, such as a dual active bridge, a flyback converter, a series or parallel resonant converter, and a half bridge or full bridge converter.

Referring to FIG. 4, a RF pulse generator 20 can comprise a power combiner 18 for combining the outputs 16 of a multiplicity of RF power amplifiers 15₁-15_{N} into a combined output 26. Each RF amplifier 15₁-15_{N} is connected to a respective DC/DC converter 14₁-14_{N} which provides the supply voltage to the respective RF amplifier. The RF pulse generator (such as block 153 in FIG. 1) is not shown in FIG. 4 for clarity purposes. All the DC/DC converters 14₁-14_{N} have their input terminals connected to the DC link 13. Hence, all DC/DC converters 14₁-14_{N} are supplied with the same bus voltage V_{BUS} and each of the N DC/DC converters can be independently controlled to provide a predetermined supply voltage V_{DD,1}-V_{DD,N}, which can be same or different. A suitable combiner is disclosed in WO 2020/058361.

### COMPARATIVE EXAMPLE

In this comparative example, the diagram of FIG. 1 was considered, which was further adapted in that no DC/DC converter 14 was utilized and the bus voltage V_{BUS} was directly supplied as supply voltage (V_{DD}) of the RF amplifier 15, i.e. V_{BUS}=V_{DD}. The allowable voltage droop (dV_{BUS}) was limited to 0.1 V and V_{DD}=50 V. The case in which the peak power output by the RF amplifier P_{RF_SUP}=10 kW and the pulse duration T_{RF}=5 ms was considered. The required capacitance of capacitor bank C_{BUS} for energy storage device 12 was calculated as:

$${C}_{BUS} = [ ( {P}_{RF\_SUP} / {V}_{BUS} ) \times {T}_{R F} ] / = {dV}_{BUS} = [ ( 10 kW / 50 V ) \times 5 ms ] / 0.1 = 10 F .$$

### EXAMPLE

In this example, the diagram of FIG. 1 was considered, including the DC/DC converter 14. A bus voltage V_{BUS}=100 V was considered with allowable voltage droop dV_{BUS}=25 V (resulting in V_{BUS} varying between 100 V and 75 V which was input to the DC/DC converter 14). The RF amplifier supply voltage V_{DD}=50 V needs to be provided by the output of the DC/DC converter 14. As in the comparative example, peak power output by the RF amplifier P_{RF_SUP}=10 kW and the pulse duration T_{RF}=5 ms. The required capacitance of capacitor bank C_{BUS} for energy storage device 12 was calculated as:
C_{BUS}=[(P_{RF_SUP}/V_{BUS})×T_{RF}]/dV_{BUS}=[(10 kW/50V)×5 ms]/25=40 mF, meaning that the energy storage device can be designed with a 250 times smaller capacitance compared to the comparative example.

Advantageously, the ratio of capacitance of the energy storage device 12 to the peak power output of the RF amplifier 15 in pulse generators according to aspects of the present disclosure (C_{BUS}/P_{RF_SUP}) is 0.100 mF/W or less, advantageously 0.050 mF/W or less, advantageously 0.025 mF/W or less, advantageously between 0.5·10⁻³ mF/W and 0.020 mF/W, advantageously between 1·10⁻³ mF/W and 0.010 mF/W. The (rated) bus voltage V_{BUS} in pulse generators according to aspects of the present disclosure is advantageously at least 50 V, at least 70 V, at least 75 V, at least 100 V, or at least 120 V. The (rated) bus voltage V_{BUS} is advantageously 1000 V or less, advantageously between 500 V or less, 300 V or less, or 200 V or less.

The RF pulse generators as described in the present disclosure can be utilized for generating an RF electromagnetic field. They may find application as amplifiers in MRI apparatuses, as plasma generator, CO₂ lasers or particle accelerators. To this end, the output 16 or 26 of the pulse generators 10, 20 respectively, can be coupled to a tank circuit 30 which can include an RF coil for generating a magnetic field.

1. A device (10, 20) for amplifying a radio frequency (RF) pulse, the device comprising:
an amplifier (15) configured to amplify an RF pulsed signal, the amplifier comprising an input (151) configured to receive a supply voltage (V_{DD}),
a DC link (13) configured to supply a DC bus voltage (V_{BUS}),
an energy storage device (12) connected to the DC link,
a switched DC/DC converter (14, 24) comprising a converter input (141) connected to the DC link and a converter output (142) connected to the input (151) of the amplifier, and
a control unit (17) configured to operate the switched DC/DC converter,
wherein the switched DC/DC converter (14, 24) is configured to step down the DC bus voltage (V_{BUS}) at the converter input to the supply voltage (V_{DD}) at the converter output, and
wherein the control unit (17) is configured to operate the switched DC/DC converter (14, 24) continuously to control the supply voltage at a predetermined value during generation of the RF pulsed signal.

2. The device of claim 1, wherein the switched DC/DC converter (14) is configured to be operated at a switching frequency, wherein a ratio of the switching frequency to a repetition frequency of the RF pulse is at least 10.

3. The device of claim 1, wherein a ratio of a rated value of the DC bus voltage (V_{BUS}) to the supply voltage (V_{DD}) is at least 1.5.

4. The device of claim 1, wherein the control unit (17) is configured to switch the switched DC/DC converter (14) during amplification of a pulse of the RF pulsed signal.

5. The device of claim 1, further comprising a mains-to-DC converter (11) having an output connected to the DC link (13), the mains-to-DC converter being configured to supply energy to the energy storage device (12).

6. The device of claim 5, wherein the mains-to-DC converter (11) is an AC-to-DC converter.

7. The device of claim 1, wherein the energy storage device (12) comprises one or more storage capacitors.

8. The device of claim 7, wherein a ratio of capacitance of the energy storage device (12) to peak output power of the amplifier is between 0.5 mF/W and 100 mF/W.

9. The device (20) of claim 1, comprising a plurality of the switched DC/DC converter (14₁, 14_{N}) and a plurality of the amplifier (15₁, 15_{N}), wherein each of the plurality of amplifiers is series connected to a respective one of the plurality of switched DC/DC converters for receiving the supply voltage therefrom, wherein the plurality of amplifiers are parallel connected to an output (26) of the device.

10. The device of claim 9, wherein the output of the device (26) comprises a power combiner (18) connected to outputs of the plurality of amplifiers.

11. The device of claim 9, wherein the plurality of switched DC/DC converters are parallel connected to the DC link (13).

12. The device of claim 1, wherein the switched DC/DC converter (14) is a non-isolated converter.

13. The device of claim 1, wherein the switched DC/DC converter is an isolated converter.

14. An apparatus for generating an RF electromagnetic field, the apparatus comprising the device of claim 1.

15. The apparatus of claim 14, further comprising a coil configured to generate the RF electromagnetic field, wherein the coil is coupled to the device (10, 20).

16. A method of amplifying a RF pulse, the method comprising:
storing energy in an energy storage device (12) at a DC bus voltage (V_{BUS}),
stepping down the DC bus voltage to a supply voltage (V_{DD}) utilizing a switched DC/DC converter (14),
applying the supply voltage to an amplifier (15), the amplifier amplifying the RF pulse,
wherein the supply voltage is controlled to be at a predetermined value by switching the switched DC/DC converter (14) continuously while amplifying the RF pulse.

17. The method of claim 16, wherein a plurality of the RF pulses are amplified, the plurality of RF pulses having a pulse repetition frequency and wherein the switched DC/DC converter (14) is operated at a switching frequency, wherein a ratio of the switching frequency to the pulse repetition frequency is at least 10.

18. The method of claim 16, wherein a ratio of the DC bus voltage (V_{BUS}) to the supply voltage (V_{DD}) is at least 1.5.

19. The method of claim 16, further comprising generating the RF pulse and applying the RF pulse to the amplifier.

20. The method of claim 16 wherein the energy in the energy storage device is stored in one or more capacitors.
